(19) United States
(12) Patent Application Publication
(10) Pub. No.: US 2007/0095282 A1
(43) Pub. Date: May 3, 2007

(54) Apparatus for manufacturing semiconductor device with pump unit and method for cleaning the pump unit

(76) Inventors: Byoung-Hoon Moon, Suwon-si (KR); Yong-Wook Kim, Hwaseong-gun (KR); Tae-Ho Kim, Suwon-si (KR); Ji-Young Choi, Hwaseong-si (KR); Sung-Jae Lee, Yongin-si (KR); Seung-Kook Ahn, Hwaseong-si (KR)

Correspondence Address: F. CHAU & ASSOCIATES, LLC, 130 WOODBURY ROAD, WOODBURY, NY, 11797, US

(21) Appl. No.: 11/496,978

(22) Filed: Aug. 1, 2006

(30) Foreign Application Priority Data
Aug. 1, 2005 (KR) 10-2005-70324

(51) Int. Cl. B08B 6/00; H01L 21/306; C23C 16/00

(52) U.S. Cl. 118/715; 134/1.3; 156/345.29

(57) ABSTRACT

An apparatus for manufacturing a semiconductor device includes a chamber and an exhaust system for exhausting byproducts from the chamber and adjusting an internal pressure of the chamber. The exhaust system includes an exhaust pipe connected to the chamber, a pump unit coupled with the exhaust pipe, and a cleaning unit connected to a portion of the exhaust pipe or directly connected to the pump unit to supply a cleaning gas to the pump unit.

### CROSS-REFERENCE TO RELATED PATENT APPLICATION

This application claims priority to Korean Patent Application No. 10-2005-0070324, filed on Aug. 01, 2005, the disclosure of which is herein incorporated by reference in its entirety.

### BACKGROUND OF THE INVENTION

1. Technical Field

The present disclosure relates to an apparatus and method for manufacturing a semiconductor device and, more particularly, to an apparatus for manufacturing a semiconductor device with a pump unit and a method for cleaning the pump unit.

2. Discussion of Related Art

In general, semiconductor device fabrication involves three basic processes: deposition, photolithography, and etching. Deposition or etching equipment commonly includes a processing chamber defining a space in which wafers are loaded and processed. Processing chambers are designed to achieve and maintain a controlled environment such as by adjusting pressure within the processing chamber to a predetermined pressure. An exhaust system for exhausting reaction byproducts is provided in the chamber. Typically, the exhaust system includes an exhaust pipe connected to the chamber and pumps which are installed on the exhaust pipe. The commonly used types of pumps include a dry pump for adjusting the pressure within the chamber and a booster pump for enhancing pumping performance. If necessary, a turbo pump may be directly installed on the chamber to maintain a desired process vacuum level inside the chamber.

As the process steps are performed in the processing chamber, the reaction byproducts are deposited in the chamber and the pumps. The byproducts deposited in the chamber can begin to flake off resulting in particles that have a detrimental effect on wafer yield. The byproducts deposited in the pump increase resistance against the relative rotation between a rotor and stator of the pump, resulting in an increased mechanical load on the motor that reduces the compression performance of the pump. This reduction in the pump's compression performance can occur abruptly. In such case, the deposition process is not properly realized due to the pump malfunction.

Therefore, a need exists to periodically clean the chamber and the pumps. Generally, the pumps and chamber are cleaned simultaneously by supplying a reactive gas for cleaning the chamber and the pumps that are connected to the chamber. Alternatively, the pumps may be separated from the exhaust system and cleaned. In the case where the chamber and the pumps are cleaned simultaneously by the use of a reactive gas, since the pumps are cleaned by the same gas that has been used to clean the chamber, the cleaning efficiency with respect to the pumps is decreased. In the case where the pumps are separated from the exhaust system and cleaned, because separating and assembling the pumps is time-consuming, the length of the clean operation is increased. Increasing the length of the clean operation is undesirable because it adversely affects wafer throughput.

### SUMMARY OF THE INVENTION

In an exemplary embodiment of the present invention an apparatus for manufacturing a semiconductor device includes a chamber and an exhaust system for exhausting byproducts from the chamber and adjusting an internal pressure of the chamber. The exhaust system includes an exhaust pipe connected to the chamber, a pump unit coupled with the exhaust pipe, and a cleaning unit connected to a portion of the exhaust pipe or directly connected to the pump unit to supply a cleaning gas to the pump unit.

In an exemplary embodiment of the present invention, the pump unit includes an inlet and an outlet connecting the pump unit to the exhaust pipe, a dry pump for adjusting the internal pressure of the chamber, and a booster pump installed between the inlet and the dry pump for enhancing a pumping performance of the dry pump.

In an exemplary embodiment of the present invention, the cleaning unit includes a gas supply pipe for supplying the cleaning gas, an activation member for activating the cleaning gas, and an injection pipe for injecting the cleaning gas activated by the activation member into the pump unit.

The activation member may include a plasma generator generating plasma from the cleaning gas. The plasma generator may include a casing arranged between the injection pipe and the cleaning gas supply pipe, a first electrode provided on a first surface of the casing, a second electrode provided on a second surface of the casing arranged facing the first surface, and a power source for supplying power to the first or second electrode.

The activation member may include a heater for heating the cleaning gas.

In an exemplary embodiment of the present invention, the cleaning gas includes an etching gas for etching the byproducts deposited in the pump unit and an auxiliary gas chemically bonding to a first component of the etching gas, which is not directly related to the etching, to prevent a second component of the etching gas, which is directly related to the etching, from reacting with the first component.

In an exemplary embodiment of the present invention, the cleaning gas supply pipe includes an etching gas supply pipe for supplying the etching gas to the activation member and an auxiliary gas supply pipe for supplying the auxiliary gas to the activation.

In an exemplary embodiment of the present invention, the cleaning unit includes a first flow adjusting unit installed on the etching gas supply pipe, a second flow adjusting unit installed on the auxiliary gas supply pipe, and a flow control unit for controlling the first and second flow adjusting units. A mixture rate of the etching gas and the auxiliary gas can be adjusted by the first and second flow adjusting units.

In an exemplary embodiment of the present invention, the injection pipe is inserted into a pipe provided in the pump unit and an outlet of the injection pipe is designed to dispense the cleaning gas in a direction that is substantially identical to a direction in which a gas flows in the exhaust system. Preferably, the outlet of the injection pipe is designed to dispense the cleaning gas in a direction that is substantially parallel to the direction in which the gas flows in the exhaust system.

In an exemplary embodiment of the present invention, the injection pipe includes a showerhead installed on the outlet, the showerhead being provided with a plurality of dispensing holes for widely dispensing the cleaning gas.

In an exemplary embodiment of the present invention, the cleaning unit is connected to the inlet of the pump unit or to a pipe connecting the inlet to the booster pump. The cleaning unit may be connected to a pipe connecting the booster pump to the dry pump. The dry pump may include a plurality of stages and the cleaning unit may be connected to one of pipes connecting the stages. The cleaning unit may be connected to a pipe connecting the dry pump to the outlet.

In an exemplary embodiment of the present invention, the exhaust system further includes a load measuring unit for measuring a load of the motor provided in the pump unit and a main controller controlling a cleaning timing of the pump unit according to a measured value transmitted from the load measuring unit.

In an exemplary embodiment of the present invention, a method of cleaning a pump unit connected to an exhaust pipe for exhausting reacting byproducts out of a chamber used in semiconductor device manufacturing includes: connecting a cleaning gas supply pipe to a portion of the exhaust pipe or to the pump unit directly; and supplying the cleaning gas to the pump unit through the cleaning gas supply pipe. The cleaning gas may be directly supplied to a region where a relatively large amount of the reaction byproducts are deposited in the pump unit.

In an exemplary embodiment of the present invention, the cleaning of the pump unit is performed while the process is being performed in the chamber. The cleaning of the pump unit may be performed when a predetermined number of processes for processing the wafers are performed in the chamber or a predetermined time has lapsed. The cleaning of the pump unit may be performed by continuously supplying the cleaning gas into the pump unit at a predetermined time interval regardless of a progress of the process. The cleaning of the pump unit may be performed only when the chamber is being cleaned. The cleaning of the pump unit may be performed only when there is an error after a self-diagnosis is performed for the pump unit. A current flowing in a motor of the pump unit may be continuously measured and the cleaning of the pump unit may be performed when a measured value of the current is outside a preset range.

### BRIEF DESCRIPTION OF THE DRAWINGS

The present invention will become readily apparent to those of ordinary skill in the art when descriptions of exemplary embodiments thereof are read with reference to accompanying drawings.

FIG. 1 is a schematic view of an apparatus for manufacturing a semiconductor device according to an exemplary embodiment of the present invention.

FIG. 2 is a view of the exhaust system of FIG. 1, according to an exemplary embodiment of the present invention.

FIG. 3 is a view of the activation member of FIG. 2, according to an exemplary embodiment of the present invention.

FIG. 4 is a view of the activation member of FIG. 2, according to an exemplary embodiment of the present invention.

FIG. 5 is a view of an injection pipe inserted in a distribution pipe according to an exemplary embodiment of the present invention.

FIG. 6 is a view of an injection pipe inserted in a distribution pipe according to an exemplary embodiment of the present invention.

FIGS. 7A through 7E are views illustrating a variety of locations of the distribution pipes coupled to a pump unit according to exemplary embodiments of the present invention.

FIG. 8 is a schematic view of the exhaust system of FIG. 1, according to an exemplary embodiment of the present invention.

### DESCRIPTION OF EXEMPLARY EMBODIMENTS

Hereinafter, exemplary embodiments of the present invention will be described in detail with reference to the accompanying drawings. In the drawings, the size and relative sizes of layers and regions may be exaggerated for clarity.

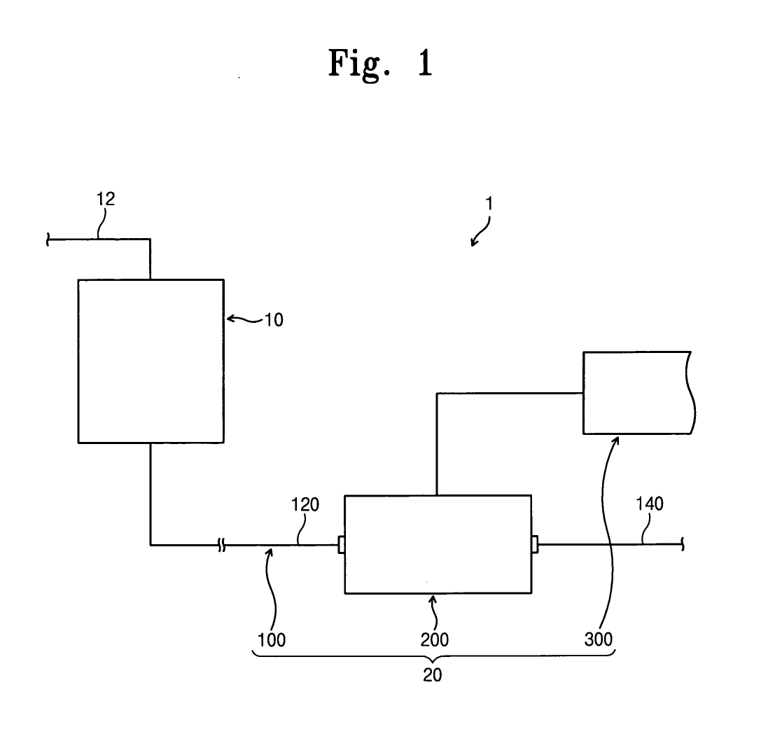

FIG. 1 is a schematic view of an apparatus for manufacturing a semiconductor device according to an exemplary embodiment of the present invention. Referring to FIG. 1, a semiconductor device manufacturing apparatus 1 includes a chamber 10 and an exhaust system 20. The chamber 10 is configured with a substrate support for supporting a semiconductor substrate such as a wafer (not shown). A process gas that will be deposited on the wafer is supplied into the chamber 10 through a gas supply pipe 12. The exhaust system 20 is coupled with the chamber 10. The exhaust system 20 is operable to maintain an internal pressure of the chamber 10 at a process pressure and exhaust reaction byproducts out of the chamber 10.

The exhaust system 20 of FIG. 1 includes an exhaust pipe 100, a pump unit 200 and a cleaning unit 300. The exhaust pipe 100 is connected to the chamber 10 to function as a conduit through which a gas exhausted from the chamber 10 flows. The pump unit 200 is installed on the exhaust pipe 100 to forcedly remove the gas from the chamber 10 by suction and maintain the internal pressure of the chamber at the process pressure. The cleaning unit 300 is connected to the pump unit 200. The cleaning unit 300 supplies a cleaning gas into the pump unit 200 to remove the reaction byproducts deposited in the pump unit 200. In an exemplary embodiment of the present invention, the cleaning unit 33 is directly connected to the pump unit 200 to directly supply the cleaning gas to the pump unit 200.

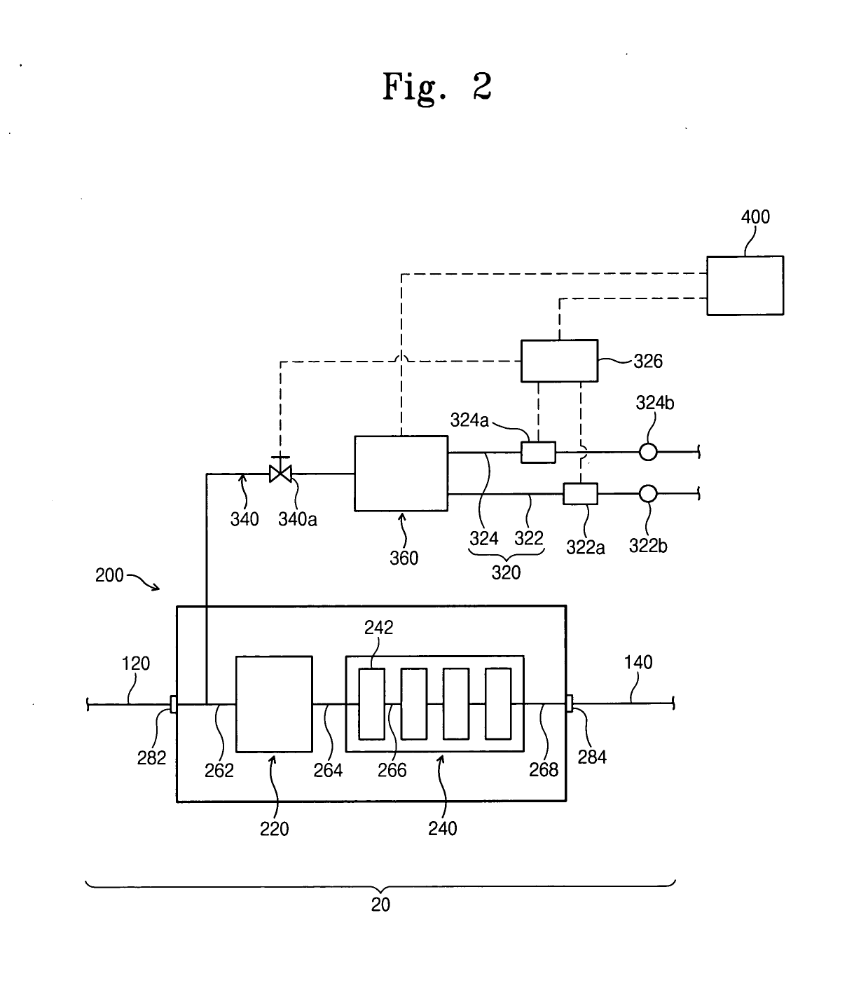

FIG. 2 shows a view of the exhaust system 20 of FIG. 1, according to an exemplary embodiment of the present invention. Referring to FIG. 2, the pump unit 200 includes an inlet 282, an outlet 284, a booster pump 220, and a dry pump 240. The pump unit 200 is connected to the exhaust pipe 120 through the inlet 282 and to the exhaust pipe 140 through the outlet 284. The reaction byproducts exhausted from the chamber 10 are directed into the pump unit 200 via the inlet 282 and exhausted out of the pump unit 200 through the outlet 284. The dry pump 240 is operable to maintain the internal pressure of the chamber 10 at the process pressure, and the booster pump 220 is operable to enhance the pumping performance of the dry pump 240.

The dry pump 240 may be arranged between the inlet 282 and the outlet 284, and the booster pump 220 may be arranged between the inlet 282 and the dry pump 240. As shown in FIG. 2, the inlet 282, the booster pump 220, the dry pump 240, and the outlet 284 are connected by the pipes 262, 264 and 268 therebetween. To maintain the internal pressure at a predetermined level, the dry pump 240 includes a plurality of stages 242 that compress air. The stages 242 are connected to each other, for example, by a pipe 266. The number and type of the stages 242 may vary according to the process pressure of the chamber 10.

Although not shown as such in FIG. 2, the pump unit 200 may include only the dry pump 240. It is to be understood that various types of dry pump 240 are suitable. For example, the dry pump 240 may include only one stage 242 or a plurality of stages 242, or a screw-shaped compressor instead of the stages.

As the process is performed, the reaction byproducts are deposited in the pump unit 200. The reaction byproducts may be deposited in the pipes 262, 264, 266, and/or 268 and/or in the pump 220 and/or in the pump 240. When a sufficient amount of the reaction byproducts are deposited in the pump unit 200, the pump performance is degraded, as a result of which the internal pressure of the chamber 10 may not be maintained at the desired process pressure.

The cleaning unit 300 is provided to clean the pump unit 200. Although not shown as such in FIG. 1, the cleaning unit 300 may be connected to the exhaust pipe 120, for example, near the pump unit 200 to supply the cleaning gas to the pump unit 200. The cleaning unit 300 may be directly connected to the pump unit 200, as shown in FIG. 1, to supply the cleaning gas into the pump unit 200.

Referring to FIG. 2, the cleaning unit 300 includes a cleaning gas supply pipe 320, an injection pipe 340 and an activation member 360. The cleaning gas may be supplied from a cleaning gas storage unit (not shown) to the pump unit 200 via the gas supply pipe 320. The activation member 360 is installed on the cleaning gas supply pipe 320 to activate the cleaning gas. The injection pipe 340 is directly connected into the pump unit 200 to supply the activation gas to the pump unit 200.

The cleaning gas may include an etching gas and an auxiliary gas. The etching gas serves to etch the reaction byproducts deposited in the pump unit 200. In an exemplary embodiment of the present invention, the etching gas includes a first and second component, wherein the first component is not directly related to the cleaning and the second component is directly related to the cleaning. Before the second component of the etching gas that is directly related to the cleaning is chemically bonded to the reaction byproducts in the pump unit 200, the reaction byproducts may bond to the first component of the etching gas that is not directly related to the cleaning. This reduces cleaning efficiency. In accordance with an exemplary embodiment of the present invention, an auxiliary gas is provided that includes a component that can easily chemically bond to the first component of the etching gas.

For example, when a material to be deposited on the wafer is tungsten, NF₃ is used as the etching gas and O₂ is used as the-auxiliary gas. In the NF₃, a component that is directly related to the etching is F₂ that reacts with the tungsten to generate WFₓ, and a component that is not directly related to the etching is the N that bonds to the O₂ to form N₂O. In the pump unit 200, according to an exemplary embodiment of the present invention, the N bonds to the O₂, and the N₂ is prevented from bonding to the F.

Perfluoro carbon, ClF₃, or F₂ may be used as the etching gas and N₂ may be used as the auxiliary gas. It is to be understood that various combinations of etching gas and auxiliary gas are suitable for implementing the present invention.

As shown in FIG. 2, the cleaning gas supply pipe 320 includes an etching gas supply pipe 322 and an auxiliary gas supply pipe 324. The etching gas and the auxiliary gas may be mixed with each other and then supplied into the pump unit 200. The etching gas supply pipe 322 and the auxiliary gas supply pipe 324 are connected to the activation member 360, and the gases can be mixed in the activation member 360. A separated mixer (not shown) for mixing the etching gas with the auxiliary gas may be provided. Alternatively, the etching gas and the auxiliary gas may be separately supplied to the pump unit 200.

To adjust a mixing ratio of the etching gas and the auxiliary gas, flow adjusting units 322a and 324a may be installed on the etching gas supply pipe 322 and the auxiliary gas supply pipe 324, respectively. For example, a mass flowmeter or a flow control valve may be used as the flow adjusting units 322a and 324a. Regulators 322b and 324b may be installed on the etching gas supply pipe 322 and the auxiliary gas supply pipe 324, respectively. The flow adjusting units 322a and 324a are controlled by a flow control unit 326. The mixing ratio of the etching gas and the auxiliary gas can be adjusted by manipulating the flow control unit 326.

The injection pipe 340 is directly connected to the pump unit 200 to supply the cleaning gas into the pump unit 200. A valve 340a for selectively closing the passage of the injection pipe 340 is installed on the injection pipe 340. For example, the valve 340a may comprise a solenoid valve that can be electrically controlled. The valve 340a is controlled by the flow control unit 326.

The cleaning gas may be supplied into the pump unit 200 in a state where it is activated.

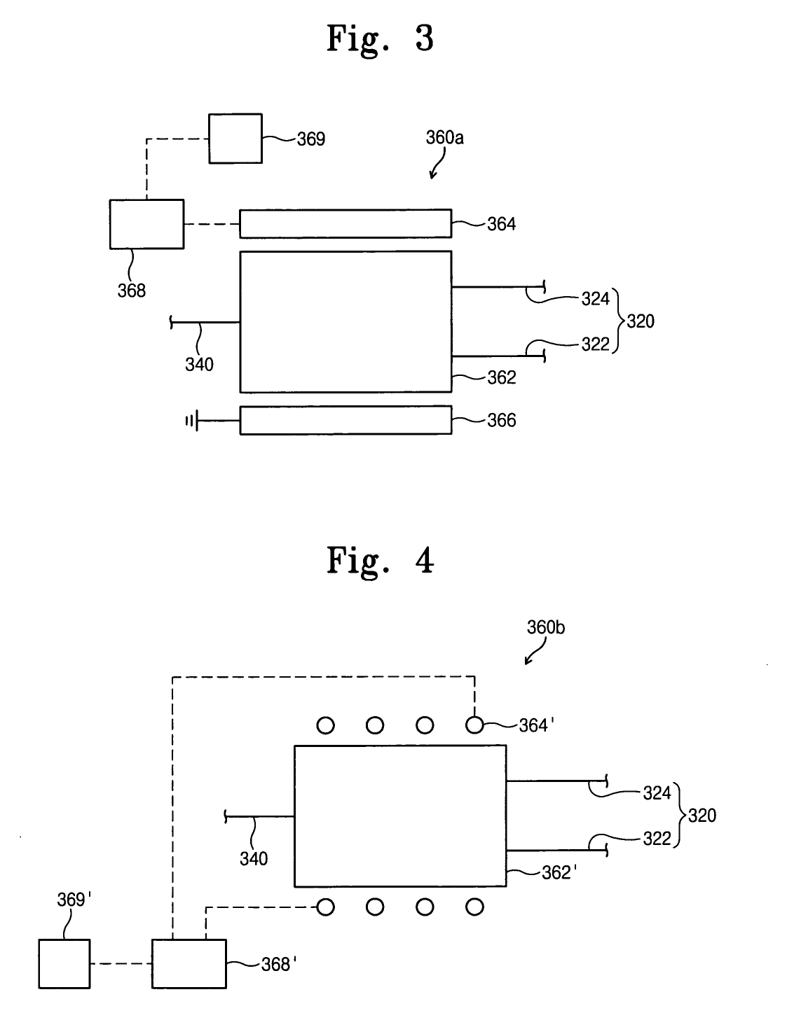

FIG. 3 is a view of the activation member 360 of FIG. 2, according to an exemplary embodiment of the present invention. Referring to FIG. 3, the activation member 360 comprises a plasma generator 360a activating the cleaning gas to a plasma state. The plasma generator 360a includes a casing 362, a first electrode 364, a second electrode 366, and a power source 368. The etching gas supply pipe 322 and the auxiliary gas supply pipe 324 are connected to a first face of the casing 362. The injection pipe 340 is connected to a second face of the casing 362. The first electrode 364 is installed on a first side surface of the casing 362 and the second electrode 366 is installed on a second side surface of the casing 362 arranged facing the first side surface. The power source 368 applies a voltage, such as a high voltage, to the first electrode 364. The second electrode 366 may be grounded. A radio frequency generator for applying a radio frequency may be used as the power source 368. The radio frequency applied from the radio frequency generator is controlled by a power control unit 369.

FIG. 4 is a view of the activation member 360 of FIG. 2, according to an exemplary embodiment of the present invention. As shown in FIG. 4, the activation member 360 may include a heater 360b activating the cleaning gas to an ion state. The heater 360b includes a casing 362′, a heat wire 364′, and a power source 368′. The etching gas supply pipe 322 and the auxiliary gas supply pipe 324 are connected to a first surface of the casing 362′ and the injection pipe 340 is connected to a second surface of the casing 362′. The heat wire 364′ is installed on an outer circumference of the casing 362′. That is, the heat wire 364′ is wound around the casing 362′ and supplied with power from the power source 368′. The power source 368′ is controlled by a power control unit 369′.

The etching gas and the auxiliary gas flow into the casing 362 of the activation member 360 through the etching gas supply pipe 322 and the auxiliary gas supply tube 324, after which they are mixed in the casing 362 and activated to a radical or ion state. Then, the mixture gas in the radical or ion state is directly supplied into the pump unit 200.

FIG. 5 is a view of an injection pipe 340 inserted in a distribution pipe according to an exemplary embodiment of the present invention. The injection pipe 340 is connected to the activation member 360. The injection pipe 340 penetrates the pipe 262 (264, 266 or 268) of the pump unit 200 such that an outlet thereof is disposed in the pipe 262 (264, 266 or 268). The outlet of the injection pipe 340 is designed to dispense the cleaning gas in a first direction, as indicated by the dotted arrow in FIG. 5, which is substantially identical to a second direction, as indicated by the solid arrow in FIG. 5, in which the gas flows through the pipes 262, 264, 266, and 268. According to an exemplary embodiment of the present invention, the cleaning gas supplied through the cleaning unit 300 can be stably supplied to a desired region while flowing through the pipes 262, 264, 266, and 268 in the direction in which the gas flows. Here, the gas flowing through the pipes 262, 264, 266, and 268 is gas exhausted from the chamber 10. In an exemplary embodiment of the present invention, the first direction is substantially identical to the second direction means that an angle θ between the gas flow direction and the cleaning gas dispensing direction is as follows: 0°≦θ≦90°.

For example, the injection pipe 340 includes an insertion portion 342 substantially perpendicularly inserted into the pipe 262 (264, 266 or 268) and a dispensing portion 344 extending from an end of the insertion 242 in the first direction. The insertion and dispensing portions 342 and 344 may be identical in diameter. In an exemplary embodiment of the present invention, the outlet of the injection pipe 340 is designed to dispense the cleaning gas in a direction that is substantially parallel to the gas flow direction in the pipe 262 (264, 266 or 268).

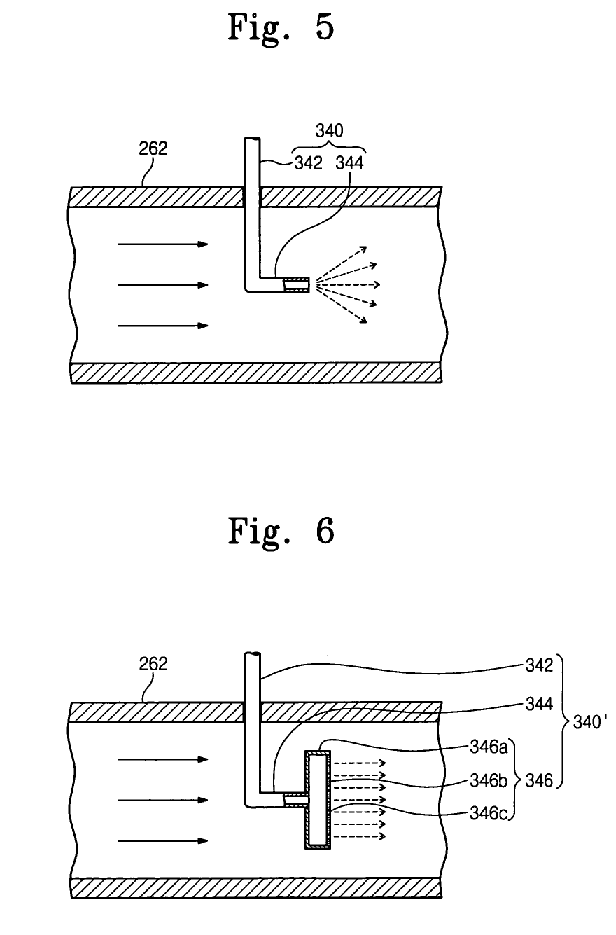

FIG. 6 shows a view of the injection pipe 340 according to an exemplary embodiment of the present invention. Referring to FIG. 6, the injection pipe 340 is designed to widely dispense the cleaning gas. The injection pipe 340 includes an insertion portion 342, a dispense portion 344 and a showerhead 346. Since the insertion portion 342 and the dispensing portion 344 are basically identical to those of FIG. 5, further description thereof will be omitted in the interests of simplicity and clarity. The showerhead 346 uniformly dispenses the cleaning gas in a relatively wide range. The showerhead 346 is coupled to an end of the dispensing portion 344. The shower head 346 includes a side wall 346a and a spraying plate 346b that define a space in which the cleaning gas exhausted from the dispensing portion 344 temporarily stays before it is supplied into the pipe 262 (264, 266 or 268). The spraying plate 246b is provided with a plurality of spraying holes 346c through which the cleaning gas introduced into the space is widely dispensed into the pipe 262 (264, 266 or 268).

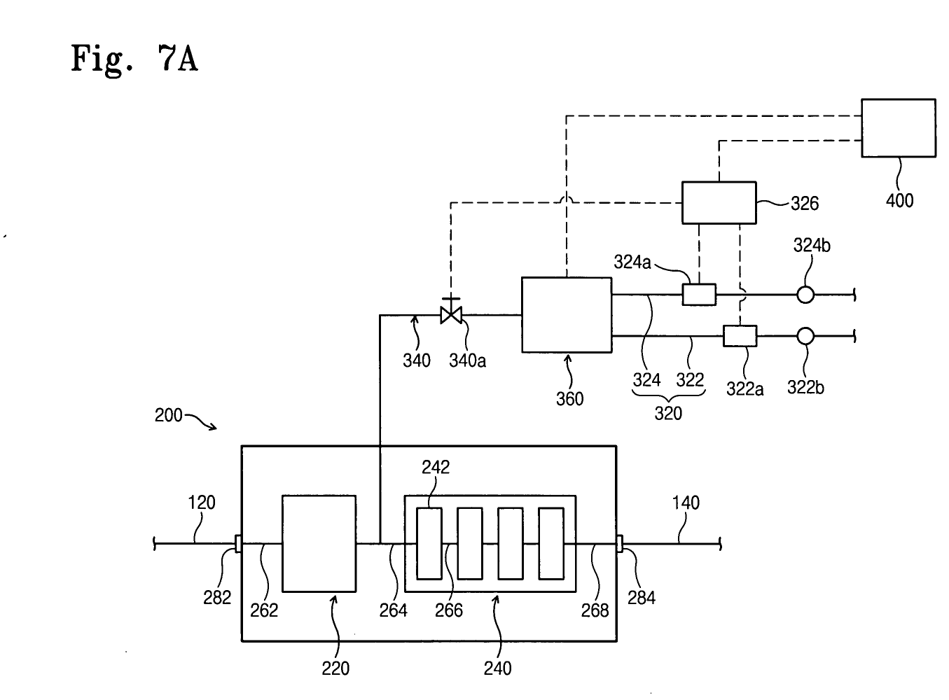

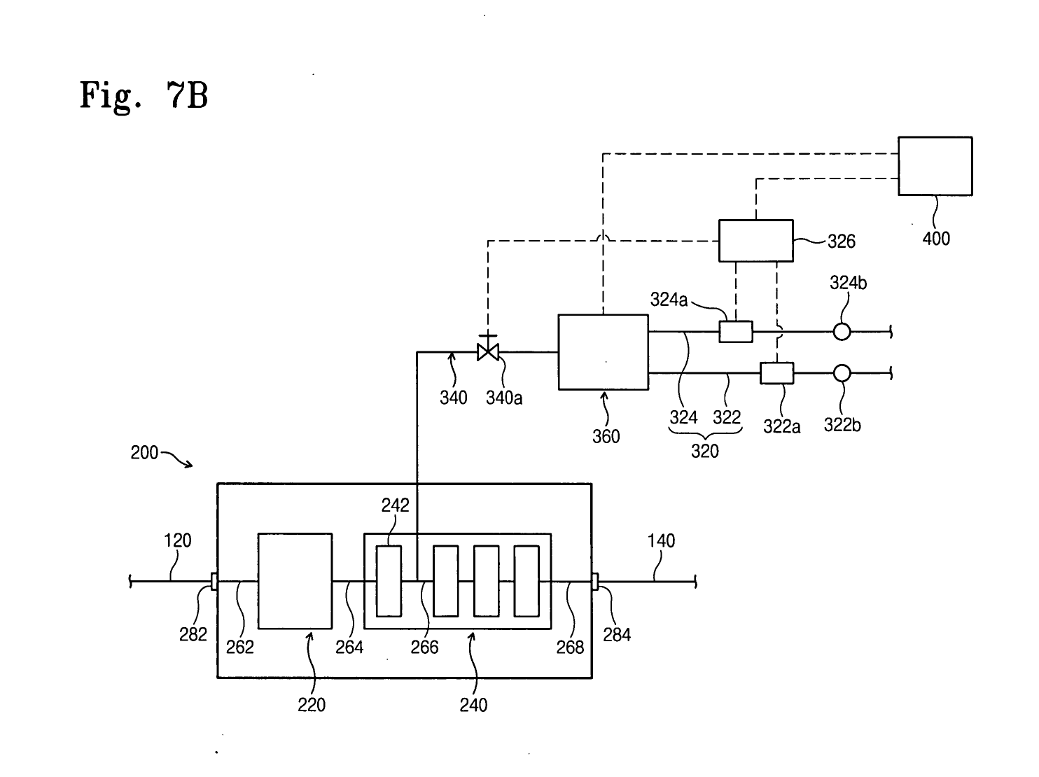

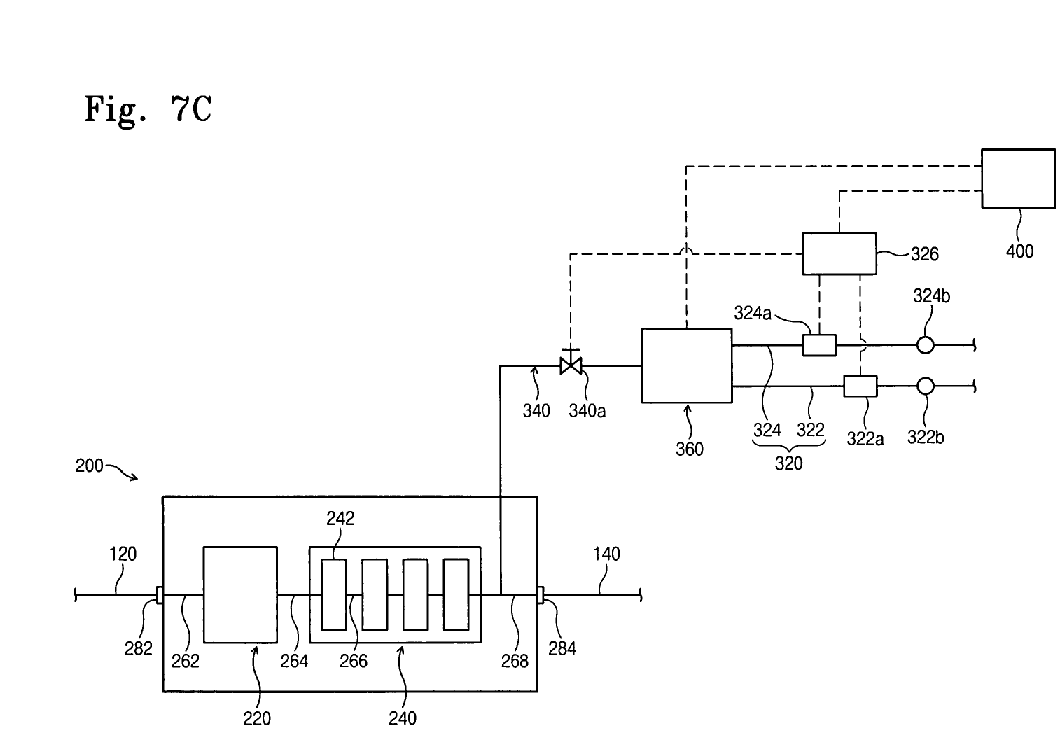

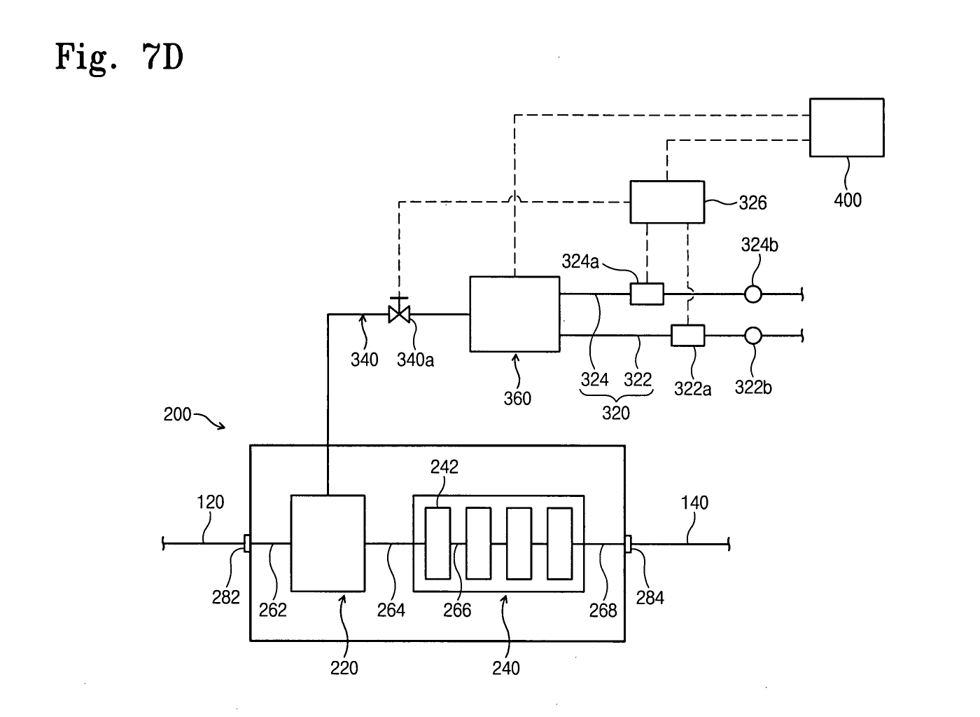

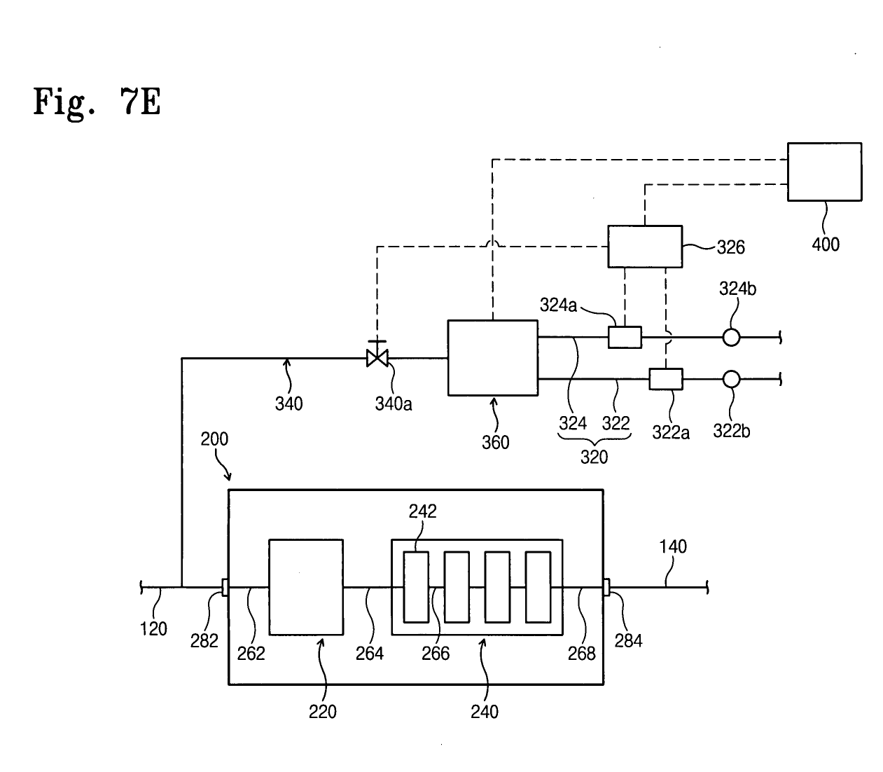

The injection pipe 240 may be connected to various locations of the pump unit 200. For example, as shown in FIG. 2, the injection pipe 340 may be connected to the pipe 262 interconnecting the inlet 282 and the booster pump 220. As shown in FIG. 7A, the injection pipe 240 may be connected to the pipe 264 connecting the booster pump 220 to the dry pump 240. As shown in FIG. 7B, the injection pump 340 may be connected to the pipe 266 connecting the stages 242 arranged in the dry pump 240. As shown in FIG. 7C, the injection pump 340 may be connected to the pipe 268 connecting the outlet 284 to the dry pump 240. As shown in FIG. 7D, the injection pump 340 may be directly connected to the booster pump 220. As shown in FIG. 7E, the injection pump 340 may be coupled to a portion of the exhaust pipe 120 near the pump unit 20.

Because the internal pressure of the exhaust pipe 140 connected to the outlet 284 of the pump unit 200 shown in FIG. 2 is higher than that of the exhaust pipe 120 connected to the inlet 282, the amount of reaction byproducts deposited in the exhaust pipe 140 may be greater than that of the reaction byproducts deposited in the exhaust pipe 120. When the injection pipe 340 is directly connected to the outlet 284 or to the pipe 268 connecting the dry pump 240 to the outlet 284 in accordance to an exemplary embodiment of the present invention, the cleaning efficiency with respect to the pump unit 200 and the exhaust pipe 100 connected to the outlet 284 can be improved.

The connection location of the injection pipe 340 to the pump unit 200 may be set at a location where a relatively large amount of byproducts are deposited in the pump unit 200. For example, when the relatively large amount of the byproducts are deposited in the booster pump 220 of the pump unit 200, as shown in FIG. 2, the injection pipe 340 may be connected to the pipe 262 connecting the inlet 282 to the booster pump 220 or directly connected to the booster pump 220.

Although not shown as such in FIGS. 2 and 7A through 7E, a plurality of injection pipes 340 may be installed on different locations of the exhaust pipe 120, for example, near the pump unit 200, or directly connected to the pump unit 200.

The flow control unit 326 and the power control unit 369 are controlled by a main control unit 400 controlling an overall operation of the apparatus. The main control unit 400 controls the cleaning timing of the pump unit 200 by controlling the flow control unit 326 and the power control unit 369.

The cleaning of the pump unit 200 may be periodically performed. For example, when a predetermined number of processes for processing wafers is performed in the chamber 10 or a predetermined time elapses, the main controller 400 controls the flow control unit 326 and the power control unit 369 to clean the pump unit.

The cleaning of the pump unit 200 may be continuously performed. For example, when the process is being performed in the chamber 10, the main control unit 400 controls the flow control unit 326 and the power control unit 369 such that the cleaning gas can be continuously supplied into the pump unit 20 at a predetermined time interval regardless of the current processing stage.

The cleaning of the pump unit 200 may be performed with the cleaning of the chamber 10. For example, the main control unit 400 controls the flow control unit 326 and the power control unit 369 such that the cleaning of the pump unit 200 can be realized when the chamber 10 is cleaned.

The cleaning of the pump unit 200 may be performed by the manipulation of a worker periodically or aperiodically. The worker may manipulate the main control unit 400 directly or remotely.

The pump unit 200 may be cleaned depending on when the apparatus operates or on the production circumstances. For example, the main control unit 400 controls the flow control unit 326 and the power control unit 369 such that the pump unit 200 can be cleaned at a predetermined point in time when the apparatus is not operated.

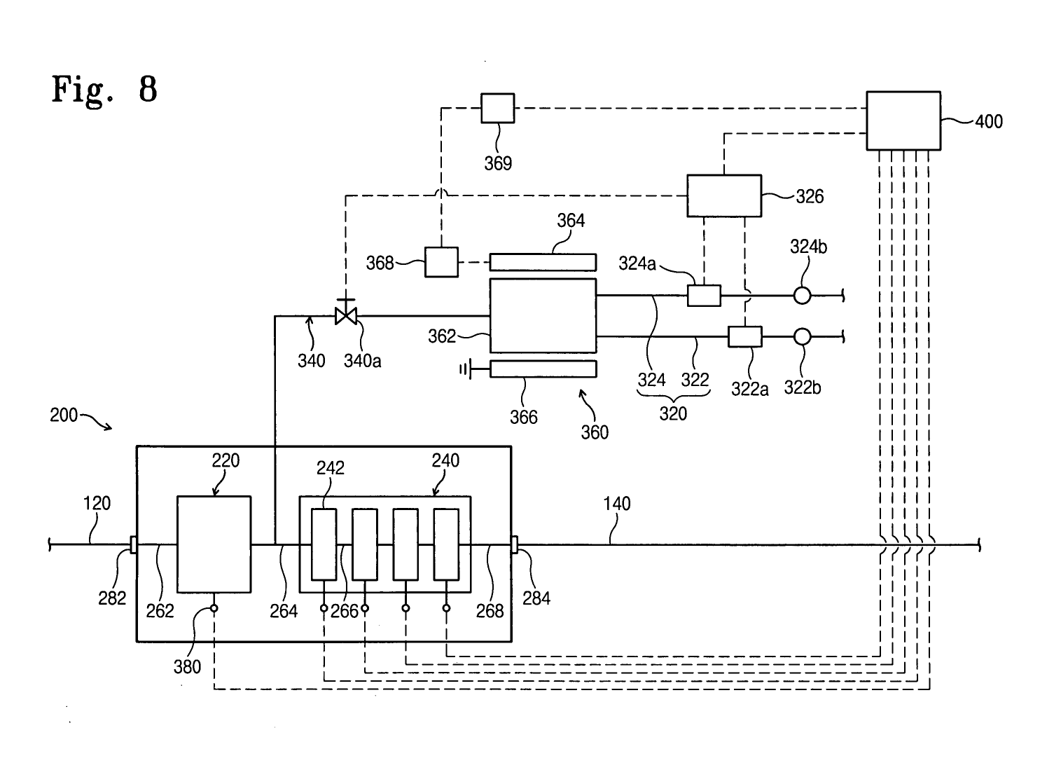

The pump unit 200 may be cleaned through a self-diagnosis method. For example, when the process is being performed and a load out of a range preset in a motor (not shown) provided on the pump unit 200 is applied, the main control unit 400 controls the flow control unit 326 and the power control unit 369 to clean the pump unit 200. For example, as shown in FIG. 8, measuring units 380 are included for measuring currents flowing in the motors provided on the booster pump 220 and the stages 242. The measuring units 380 transmit measured values to the main control unit 400. When the measured values fall out of the preset range, the main control unit 400 controls the flow control unit 326 and the power control unit 369 to clean the pump unit 200.

According to an exemplary embodiment of the present invention, the pump unit is cleaned by directly supplying the cleaning gas to the pump unit, and the cleaning efficiency is improved as compared with the case where the pump unit is cleaned by the same cleaning gas used to clean the chamber.

In an exemplary embodiment of the present invention, the pump unit can be cleaned in a state where the pump unit is connected to the exhaust pipe, and because there is no need to separate the pump unit from the exhaust pipe, equipment operating time can be increased and cleaning can be easily performed.

According to an exemplary embodiment of the present invention, when the pump is operating as the process is being performed in the chamber, the pump unit can be cleaned and the equipment operation rate may be improved.

According to an exemplary embodiment of the present invention, an etching gas and an auxiliary gas are used as the cleaning gas, and the components of the etching gas that are activated to a radical or ion state may not bond to each other in the pump unit.

Furthermore, since the pump unit can be cleaned periodically or at an appropriate point in time, the pump unit can be maintained at or restored to its initial state. Therefore, the service life of the pump unit increases and a reduction in the equipment operating time due to a malfunction of the pump unit can be minimized or prevented.

Although exemplary embodiments of the present invention have been described in detail with reference to the accompanying drawings for the purpose of illustration, it is to be understood that the inventive processes and apparatus should not be construed as limited thereby. It will be readily apparent to those of reasonable skill in the art that various modifications to the foregoing exemplary embodiments can be made without departing from the scope of the invention as defined by the appended claims, with equivalents of the claims to be included therein.

What is claimed is:

1. An apparatus for manufacturing a semiconductor device, the apparatus comprising:
a chamber; and
an exhaust system for exhausting byproducts from the chamber and adjusting an internal pressure of the chamber,
wherein the exhaust system includes:
an exhaust pipe connected to the chamber;
a pump unit coupled with the exhaust pipe; and
a cleaning unit connected to a portion of the exhaust pipe or directly connected to the pump unit to supply a cleaning gas to the pump unit.

2. The apparatus of claim 1, wherein the pump unit comprises:
an inlet and an outlet connecting the pump unit to the exhaust pipe;
a dry pump for adjusting the internal pressure of the chamber; and
a booster pump coupled between the inlet and the dry pump for enhancing a pumping performance of the dry pump.

3. The apparatus of claim 2, wherein the cleaning unit is connected to the inlet of the pump unit or to a pipe connecting the inlet to the booster pump.

4. The apparatus of claim 2, wherein the cleaning unit is connected to a pipe connecting the booster pump to the dry pump.

5. The apparatus of claim 2, wherein the dry pump includes a plurality of stages and the cleaning unit is connected to one of pipes connecting the stages.

6. The apparatus of claim 2, wherein the cleaning unit is connected to a pipe connecting the dry pump to the outlet.

7. The apparatus of claim 1, wherein the cleaning unit comprises:
a gas supply pipe for supplying the cleaning gas;
an activation member for activating the cleaning gas; and
an injection pipe for injecting the cleaning gas activated by the activation member into the pump unit.

8. The apparatus of claim 7, wherein the activation member includes a plasma generator generating plasma from the cleaning gas.

9. The apparatus of claim 8, wherein the plasma generator comprises:
a casing arranged between the injection pipe and the cleaning gas supply pipe;
a first electrode provided on a first surface of the casing;
a second electrode provided on a second surface of the casing arranged facing the first surface; and
a power source for supplying power to the first electrode or the second electrode.

10. The apparatus of claim 7, wherein the activation member includes a heater for heating the cleaning gas.

11. The apparatus of claim 7, wherein the cleaning gas comprises:
an etching gas for etching the byproducts deposited in the pump unit; and
an auxiliary gas chemically bonding to a first component of the etching gas, which is not directly related to the etching, to prevent a second component of the etching gas, which is directly related to the etching,-from reacting with the first component.

12. The apparatus of claim 11, wherein the cleaning gas supply pipe comprises:
an etching gas supply pipe for supplying the etching gas to the activation member; and
an auxiliary gas supply pipe for supplying the auxiliary gas to the activation member.

13. The apparatus of claim 12, wherein the cleaning unit comprises:
a first flow adjusting unit installed on the etching gas supply pipe;
a second flow adjusting unit installed on the auxiliary gas supply pipe; and
a flow control unit for controlling the first and second flow adjusting units.

14. The apparatus of claim 7, wherein the injection pipe is inserted into a pipe provided in the pump unit; and
an outlet of the injection pipe is designed to dispense the cleaning gas in a direction that is substantially identical to a direction in which a gas flows in the exhaust system.

15. The apparatus of claim 14, wherein the outlet of the injection pipe is designed to dispense the cleaning gas in a direction that is substantially parallel to the direction in which the gas flows in the exhaust system.

16. The apparatus of claim 15, wherein the injection pipe includes a showerhead installed on the outlet, the showerhead being provided with a plurality of dispensing holes for dispensing the cleaning gas.

17. The apparatus of claim 1, wherein the exhaust system further comprises:
a load measuring unit for measuring a load of the motor provided in the pump unit; and
a main controller controlling a cleaning timing of the pump unit according to a measured value transmitted from the load measuring unit.

18. The apparatus of claim 1, wherein the chamber is for performing a deposition process.

19. A method of cleaning a pump unit connected to an exhaust pipe for exhausting byproducts out of a chamber used in semiconductor device manufacturing, the method comprising:
connecting a cleaning gas supply pipe to a portion of the exhaust pipe or to the pump unit directly; and
supplying the cleaning gas to the pump unit through the cleaning gas supply pipe.

20. The method of claim 19, wherein the cleaning gas is directly supplied to a region where a relatively large amount of the byproducts is deposited in the pump unit.

21. The method of claim 19, wherein the cleaning gas is activated to a plasma state and supplied into the pump unit.

22. The method of claim 19, wherein the cleaning gas is heated by a heater and supplied into the pump unit.

23. The method of claim 23, wherein the cleaning gas comprises:
an etching gas for etching the byproducts deposited in the pump unit; and
an auxiliary gas chemically bonding to a component of the etching gas, which is not directly related to the etching, to prevent a component of the etching gas, which is directly related to the etching, from reacting with the component that is not directly related to the etching.

24. The method of claim 23, wherein flow amounts of the etching gas and the auxiliary gas can be controlled.

25. The method of claim 19, wherein the cleaning of the pump unit is performed while the process is being performed in the chamber.

26. The method of claim 19, wherein the cleaning of the pump unit is performed when a predetermined number of processes for processing wafers is performed in the chamber or a predetermined time has lapsed.

27. The method of claim 19, wherein the cleaning of the pump unit is performed by continuously supplying the cleaning gas into the pump unit at a predetermined time interval regardless of a stage of the process in progress.

28. The method of claim 19, wherein the cleaning of the pump unit is performed only when the chamber is being cleaned.

29. The method of claim 19, wherein the cleaning of the pump unit is performed only when an error results from a self-diagnosis performed for the pump unit.

30. The method of claim 29, wherein a current flowing in a motor of the pump unit is continuously measured and wherein the cleaning of the pump unit is performed when a measured value of the current is outside a preset range.

31. The method of claim 19, wherein the cleaning gas is supplied into a pipe provided in the pump unit in a direction that is substantially identical to a direction in which gas flows in the pipe.

32. The method of claim 19, wherein the pump unit includes a booster pump and a dry pump, and wherein at least one of the booster pump or the dry pump is cleaned by the cleaning gas.
